(19) United States
(12) Patent Application Publication
(10) Pub. No.: US 2025/0071906 A1
(43) Pub. Date: Feb. 27, 2025

(54) SUBSTRATE AND MODULE

(71) Applicant: Murata Manufacturing Co., Ltd., Kyoto (JP)

(72) Inventor: Ryuichi KUBO, Kyoto (JP)

(21) Appl. No.: 18/941,471

(22) Filed: Nov. 8, 2024

Related U.S. Application Data
(63) Continuation of application No. PCT/JP2023/006988, filed on Feb. 27, 2023.

(30) Foreign Application Priority Data
Jul. 6, 2022 (JP) 2022-109098

(51) Int. Cl. H05K 1/18

(52) U.S. Cl. CPC H05K 1/185; H05K 2201/09209

(57) ABSTRACT

A substrate includes a core substrate that has a first surface, a second surface facing away from the first surface, and a cavity portion therein, an electronic component and a metal post that are provided in the single cavity portion, and an encapsulating material that fills the cavity portion and has a third surface close to the first surface and a fourth surface close to the second surface, in which the metal post is exposed through a third surface and a fourth surface of the encapsulating material.

### CROSS REFERENCE TO RELATED APPLICATION

This is a continuation of International Application No. PCT/JP2023/006988 filed on Feb. 27, 2023 which claims priority from Japanese Patent Application No. 2022-109098 filed on Jul. 6, 2022. The contents of these applications are incorporated herein by reference in their entireties.

### BACKGROUND OF THE DISCLOSURE

### Field of the Disclosure

The present disclosure relates to a substrate and a module.

### Description of the Related Art

Patent Document 1 describes a printed wiring board including a core substrate having a cavity that passes through a core material, a plurality of types of electronic components housed in the cavity, and a resin that is formed in the cavity to secure the plurality of types of electronic components to the core substrate (see, for example, FIG. 1).

Patent Document 1: Japanese Unexamined Patent Application Publication No. 2019-207978

### BRIEF SUMMARY OF THE DISCLOSURE

Electronic components, such as a CPU, are assumed to be mounted on the printed wiring board described in Patent Document 1. In addition, the printed wiring board may be connected to a motherboard or the like. In such a case, an upper surface and a lower surface of the printed wiring board need be electrically connected to each other.

The core substrate of the printed wiring board described in Patent Document 1 has through-hole conductors for electrically connecting the upper surface and the lower surface to each other. However, the through-hole conductor cannot be provided in the cavity. Accordingly, for an electrical connection from an electronic component mounted immediately above the cavity to a portion immediately below the cavity on the opposite side, wiring need be routed from the cavity to the portion immediately below the cavity on the opposite side through the through-hole conductor. That is, wiring for bypassing the cavity need be provided on the upper surface and the lower surface of the printed wiring board. When such bypass wiring is formed, however, the wiring length increases disadvantageously.

The present disclosure addresses the problem described above with a possible benefit of providing a substrate having a structure that can easily connect a portion immediately above the cavity portion to a portion immediately below the cavity portion without increasing the wiring length.

A substrate according to the present disclosure includes: a core substrate that has a first surface, a second surface facing away from the first surface, and a cavity portion therein; an electronic component and a metal post that are provided in the cavity portion; and an encapsulating material that fills the cavity portion and has a third surface close to the first surface and a fourth surface close to the second surface, in which the metal post is exposed through the third surface and the fourth surface of the encapsulating material.

A module according to the present disclosure includes: the substrate according to the present disclosure; and a heating element mounted on the first surface of the core substrate, in which the heating element overlaps the metal post in top view in a direction orthogonal to the first surface, and the heating element and the metal post are directly connected to each other or connected to each other via a first material having a higher thermal conductivity than the encapsulating material.

According to the present disclosure, it is possible to provide a substrate having a structure that can easily connect a portion immediately above the cavity portion to a portion immediately below the cavity portion without increasing a wiring length.

### BRIEF DESCRIPTION OF THE SEVERAL VIEWS OF THE DRAWINGS

FIG. 1 is a sectional view schematically illustrating an example of a substrate according to an embodiment of the present disclosure.

FIG. 2 is a plan view of a core substrate and electronic components, and metal posts included in the substrate illustrated in FIG. 1.

FIG. 3 is a plan view schematically illustrating an example of the substrate according to the embodiment of the present disclosure including metal posts having a different top-view shape.

FIG. 4A is a perspective view schematically illustrating an example of a manufacturing process of a coaxial cable.

FIG. 4B is a perspective view schematically illustrating the example of the manufacturing process of the coaxial cable.

FIG. 4C is a perspective view schematically illustrating the example of the manufacturing process of the coaxial cable.

FIG. 4D is a perspective view schematically illustrating the example of the manufacturing process of the coaxial cable.

FIG. 5 is a plan view schematically illustrating an example of a substrate according to the embodiment of the present disclosure in which a portion of the metal post is the coaxial cable.

FIG. 6 is a sectional view schematically illustrating an example of a module according to an embodiment of the present disclosure.

FIG. 7 is a plan view of the module in FIG. 6 and illustrates the positional relationship between a heating element and components of the substrate.

FIG. 8 is a diagram schematically illustrating an example of a process of attaching an adhesive film for fixing electronic components to the core substrate.

FIG. 9 is a sectional view schematically illustrating an example of a process of disposing the electronic components and the metal posts on the adhesive film.

FIG. 10 is a sectional view schematically illustrating an example of a process of filling the cavity portion of the core substrate with an encapsulating material.

FIG. 11 is a sectional view schematically illustrating an example of a process of grinding or polishing the encapsulating material and the metal posts.

FIG. 12 is a sectional view schematically illustrating an example of a process of forming vias.

FIG. 13 is a sectional view schematically illustrating an example of a process of forming wiring layers.

FIG. 14 is a sectional view schematically illustrating an example of a process of forming buildup layers.

### DETAILED DESCRIPTION OF THE DISCLOSURE

A substrate and a module according to the present disclosure will be described.

However, the present disclosure is not limited to the following structure and can be applied while being modified as appropriate without departing from the concept of the present disclosure. It should be noted that a combination of two or more of desirable configurations described below also constitutes the present disclosure.

### (Substrate)

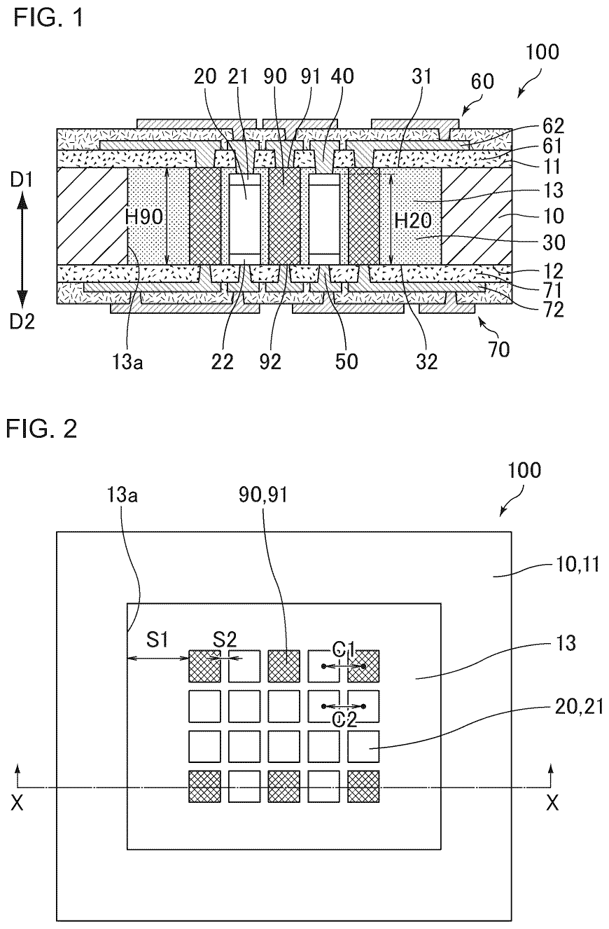

FIG. 1 is a sectional view schematically

illustrating an example of a substrate according to an embodiment of the present disclosure. FIG. 2 is a plan view of a core substrate, electronic components, and metal posts included in the substrate illustrated in FIG. 1. It should be noted that FIG. 1 is a sectional view taken along line X-X in FIG. 2.

The substrate 100 illustrated in FIGS. 1 and 2 includes a core substrate 10 that has a first surface 11, a second surface 12 facing away from the first surface 11, and a cavity portion 13 therein, electronic components 20 and metal posts 90 that are provided in the single cavity portion 13, and an encapsulating material 30 that fills the cavity portion 13 and has a third surface 31 close to the first surface 11 and a fourth surface 32 close to the second surface 12.

The substrate 100 further includes first via conductors 40 connected to first electrodes 21 of the electronic components 20 or fifth surfaces 91 of the metal posts 90, second via conductors 50 connected to second electrodes 22 of the electronic components 20 or sixth surfaces 92 of the metal posts 90, first buildup layers (rewiring layers) 60 provided in contact with the first surface 11 of the core substrate 10 and the third surface 31 of the encapsulating material 30, and second buildup layers (rewiring layers) 70 provided in contact with the second surface 12 of the core substrate 10 and the fourth surface 32 of the encapsulating material 30.

The core substrate 10 may be a resin substrate, a glass substrate, a ceramic substrate, or the like. The core substrate 10 may also be a printed wiring board having conductor wiring thereon or therein. The core substrate 10 may be an insulating support substrate (core material) formed of a resin, such as an epoxy resin, and a reinforcing material, such as a glass cloth. The support substrate may contain inorganic particles, such as silica particles and alumina particles.

The first surface 11 and the second surface 12 of the core substrate 10 are parallel to each other and constitute a pair of main surfaces of the core substrate 10 that face away from each other.

The cavity portion 13 of the core substrate 10 passes through the core substrate 10. The shape of the cavity portion 13 in plan view of the core substrate 10 is not particularly limited and may be a circle, an ellipse, an oval, a n-gon (n is an integer of 5 or more), or the like in addition to a rectangle illustrated in FIG. 2.

The substrate 100 is a component-embedded substrate in which the electronic components 20 are embedded, and the electronic components 20 are not disposed on the first surface 11 and the second surface 12 of the core substrate 10 but in the cavity portion 13 of the core substrate 10. The metal posts 90 are housed in the single cavity portion 13 in which the electronic components 20 are housed.

The electronic components 20 and the metal posts 90 may be disposed two-dimensionally in the cavity portion 13 as illustrated in FIG. 2 or may be disposed one-dimensionally in the cavity portion 13. In the former case, the electronic components 20 and the metal posts 90 may be arranged, for example, in a matrix (FIG. 2) or in a staggered manner.

The electronic components 20 are not particularly limited and may be, for example, passive components, such as capacitors (for example, multilayer ceramic capacitors (MLCCs)) and inductors. The electronic components 20 are chip components having an elongated shape, such as a rectangular parallelepiped or a cylinder.

It should be noted that, in the single cavity portion 13, a single type of the electronic components 20 may be disposed or two or more types of the electronic components 20 may be disposed in a mixed manner. In addition, in the latter case, the electronic components 20 of a single type have a single size standardized according to the size notation of the chip components. The size notation is defined by JIS (Japanese Industrial Standards) and EIA (Electronic Industries Alliance), and an example of notation in JIS is 0603. In addition, the electronic components 20 of a single type may be the same basic components of electrical circuits, such as, capacitors or inductors. In addition, the electronic components 20 of a single type may be capacitors or inductors of a single model.

In a vertical cross section, the electronic component 20 may have a shape in which the dimension of the electronic component 20 in a height direction (a direction parallel to a first direction D1 or a second direction D2 described later) parallel to a thickness direction of the core substrate 10 may be greater than the other dimensions orthogonal to the height direction. Accordingly, the electronic components 20 can be disposed with higher density.

In addition, the electronic component 20 has a first electrode 21 in a first direction D1 that is orthogonal to the second surface 12 of the core substrate 10 and faces the first surface 11 and has a second electrode 22 in a second direction D2 that is opposite to the first direction D1. The electronic components 20 having an elongated shape can be disposed with higher density by being mounted in the vertical direction as described above.

The first electrode 21 and the second electrode 22 of the electronic component 20 are located in one end portion and the other end portion, respectively, in the longitudinal direction of the electronic component 20 having an elongated shape.

The encapsulating material 30 is a member for encapsulating the electronic components 20 and the metal posts 90 in the cavity portion 13 and fills the space around the electronic components 20 and the metal posts 90 in the cavity portion 13. The encapsulating material 30 includes a resin, such as an epoxy resin, and fillers including inorganic particles, such as silica particles and alumina particles.

There is a concern that a short circuit may occur when the electronic component 20 comes into contact with the metal post 90 in the cavity portion 13. Accordingly, to prevent a short circuit from occurring when the electronic component 20 comes into contact with a side surface of the metal post 90, the side surface of the metal post 90 may be coated with an insulating resin, or an oxide film may be formed on the side surface of the metal post 90 to provide insulation.

It should be noted that the side surfaces of the metal post 90 are surfaces other than the fifth surface 91 and the sixth surface 92 of the metal post 90 and are not used for connections with other conductors.

In the substrate 100 illustrated in FIG. 1, at least one first via conductor 40 is provided for each of the electronic components 20 and the metal posts 90, and the electronic component 20 and the metal posts 90 are electrically connected to the first buildup layer 60 via the first via conductors 40. The first via conductor 40 connected to the electronic component 20 passes through at least the insulating layer 61 of the first buildup layer 60 closest to the core substrate 10 and the third surface 31 of the encapsulating material 30 and reaches the first electrode 21 of the corresponding electronic component 20. In addition, the first via conductor 40 connected to the metal post 90 passes through at least the insulating layer 61 of the first buildup layer 60 closest to the core substrate 10 and reaches the fifth surface 91 that is a surface through which the corresponding metal post 90 is exposed through the third surface 31 of the encapsulating material 30.

In addition, in the substrate 100 illustrated in FIG. 1, at least one second via conductor 50 is provided for each of the electronic components 20 and the metal posts 90, and the electronic components 20 and the metal posts 90 are electrically connected to the second buildup layer 70 via the second via conductors 50. The second via conductor 50 connected to the electronic component 20 passes through at least the insulating layer 71 of the second buildup layer 70 closest to the core substrate 10 and reaches the second electrode 22 of the corresponding electronic component 20. In addition, the second via conductor 50 connected to the metal post 90 passes through at least the insulating layer 71 of the second buildup layer 70 closest to the core substrate 10 and reaches the sixth surface 92 that is a surface through which the corresponding metal post 90 is exposed through the fourth surface 32 of the encapsulating material 30.

The first buildup layer 60 electrically connects the electronic components 20 to each other, the metal posts 90 to each other, and the electronic component 20 or the metal post 90 to another component, a through-hole, a terminal, or the like. In the first buildup layer 60, at least one insulating layer 61 and at least one wiring layer 62 are alternately laminated with each other.

Similarly, the second buildup layer 70 electrically connects the electronic components 20 to each other, the metal posts 90 to each other, and the electronic component 20 or the metal post 90 to another component, a through-hole, a terminal, or the like. In the second buildup layer 70, at least one insulating layer 71 and at least one wiring layer 72 are alternately laminated with each other.

The metal post 90 is exposed through the third surface 31 of the encapsulating material 30 and the fourth surface 32 of the encapsulating material 30. In the substrate 100 illustrated in FIG. 1, since the first via conductor 40 close to the first surface 11 of the core substrate 10 is connected to the fifth surface 91 of the metal post 90, and the second via conductor 50 close to the second surface 12 of the core substrate 10 is connected to the sixth surface 92 of the metal post 90, the first via conductor 40 and the second via conductor 50 are electrically connected to each other via the metal post 90.

That is, the metal post 90 can electrically connect the first surface 11 and the second surface 12 of the core substrate 10 to each other.

Since the metal post 90 is a columnar conductor provided in the cavity portion 13, the metal post 90 provided in the cavity portion 13 can easily connect a portion immediately above the cavity portion 13 to a portion immediately below the cavity portion 13 without increasing wiring length. That is, wiring that bypasses the cavity portion 13 is not required.

In the substrate 100 illustrated in FIG. 1, the fifth surface 91 of the metal post 90 is flush with the first surface 11 of the core substrate and the third surface 31 of the encapsulating material 30, and the fifth surface 91 of the metal post 90 is exposed through the third surface 31 of the encapsulating material 30. In the substrate manufactured by a manufacturing process described later, the positional relationship between these surfaces is the same as that described above. However, the position of the fifth surface 91 of the metal post 90 is not limited to this position and may project or be recessed from the third surface 31 of the encapsulating material 30. In other words, the fifth surface 91 of the metal post 90 may be located higher or lower than the third surface 31 of the encapsulating material 30 in FIG. 1.

When the fifth surface 91 of the metal post 90 is exposed through the third surface 31 of the encapsulating material 30, the fifth surface 91 of the metal post 90 is not covered with the encapsulating material 30, which is an insulating layer.

In addition, the fifth surface 91 of the metal post 90 may be connected directly to the conductor (the first via conductor 40 in FIG. 1) close to the first surface 11 of the core substrate 10.

In addition, a relatively thin insulator or a highly conductive resin may be present between the fifth surface 91 of the metal post 90 and the conductor close to the first surface 11 of the core substrate 10.

Similarly, in the substrate 100 illustrated in FIG. 1, the sixth surface 92 of the metal post 90 is flush with the second surface 12 of the core substrate and the fourth surface 32 of the encapsulating material, and the sixth surface 92 of the metal post 90 is exposed through the fourth surface 32 of the encapsulating material 30. In the substrate manufactured by the manufacturing process described later, the positional relationship between these surfaces is the same as that described above. However, the position of the sixth surface 92 of the metal post 90 is not limited to this position and may project or be recessed from the fourth surface 32 of the encapsulating material 30. In other words, the sixth surface 92 of the metal post 90 may be located lower or higher than the fourth surface 32 of the encapsulating material 30 in FIG. 1.

When the sixth surface 92 of the metal post 90 is exposed through the fourth surface 32 of the encapsulating material 30, the sixth surface 92 of the metal post 90 is not covered with the encapsulating material 30, which is an insulating layer. In addition, the sixth surface 92 of the metal post 90 may be connected directly to the conductor (the second via conductor 50 in FIG. 1) close to the second surface 12 of the core substrate 10. In addition, a relatively thin insulator or a highly conductive resin may be present between the sixth surface 92 of the metal post 90 and the conductor close to the second surface 12 of the core substrate 10.

The metal post 90 may have a shape in which the dimension of the metal post 90 in the height direction parallel to the thickness direction of the core substrate 10 may be greater than the other dimensions orthogonal to the height direction. This shape can also be referred to as a columnar shape, and the longitudinal direction of the columnar metal post 90 is parallel to the thickness direction of the core substrate 10.

The metal post 90 is made of a metal material, such as copper or a copper alloy. Since the metal post 90 is made of a metal material and is highly conductive, a linear electrical connection from a portion immediately above the cavity portion 13 to a portion immediately below the cavity portion 13 can be made with low electrical resistance. Since copper and copper alloys are materials having low volume resistivity, the electrical resistance can be further reduced. In addition, the heat dissipation effect from the portion immediately above the cavity portion 13 to the portion immediately below the cavity portion 13 can be obtained.

The relationship between the electronic components and the metal posts in the single cavity portion will be described.

FIG. 2 illustrates the electronic components 20 and the metal posts 90 provided in the cavity portion 13. Although the electronic components 20 and the metal posts 90 are disposed in a grid pattern, the disposition pattern is not particularly limited and may be a staggered pattern or any other pattern.

In FIG. 2, the distance between the metal post 90 and a wall surface 13a of the cavity portion 13 is indicated by double-headed arrow S1, and the distance between the metal post 90 and the electronic component 20 closest to the metal post 90 is indicated by double-headed arrow S2. In addition, the distance S2 between the metal post 90 and the electronic component 20 closest to the metal post 90 may be less than the distance S1 between the metal post 90 and the wall surface 13a of the cavity portion 13. In this case, when the electronic component 20 generates heat during operation, the heat generated by the electronic component 20 can be dissipated to the outside via the metal post 90. In other words, since the dissipation effect of the metal post does not easily work when the metal post is disposed away from the electronic component in the single cavity portion, the metal post may be disposed near the electronic component.

The distances S1 can be obtained by image analysis of a photograph of the substrate 100. More specifically, an enlarged photograph of a cross section parallel to the second surface 12 of the core substrate 10 is taken by a scanning electron microscope (SEM) or a transmission electron microscope (TEM), line segments are drawn for outlines facing each other for each of the metal post 90 and the wall surface 13a of the cavity portion 13 by using image analysis software, and the average distance between the line segments is obtained. Then, the average distances between the wall surface 13a of the cavity portion 13 and all metal posts 90 are obtained, and the average value is determined as the distance S1. An X-ray photograph may be used instead of a photograph taken by a scanning electron microscope (SEM) or a transmission electron microscope (TEM).

The distance S2 is obtained by image analysis of a photograph of the substrate 100. More specifically, an enlarged photograph of a cross section parallel to the second surface 12 of the core substrate 10 is taken by a scanning electron microscope (SEM) or a transmission electron microscope (TEM), and line segments are drawn for outlines facing each other for each of the electronic components 20 closest to the metal post 90 by using image analysis software, and the average distance between the line segments is obtained. Then, the average distances between the metal post 90 and the electronic components 20 closest to the metal post 90 are obtained for all the metal posts 90, and the average value is determined as the distance S2. An X-ray photograph may be used instead of a photograph taken by a scanning electron microscope (SEM) or a transmission electron microscope (TEM).

It should be noted that, when the electronic component generates heat during operation, the temperature of the component during operation is higher than that of the component during non-operation. The temperature of the electronic component during operation is, for example, approximately 100° C.

Since the metal post 90 made of a metal material has high thermal conductivity, the heat dissipation effect thereof is high. The thermal conductivity of the material of the metal post 90 may be 100 W/mK or more, may also be 300 W/mK or more.

In the substrate 100 illustrated in FIG. 2, the plurality of electronic components 20 are provided in the cavity portion 13. In addition, the distance between the central axis of the metal post 90 and the central axis of the electronic component 20 closest to the metal post 90 is indicated by double-headed arrow C1, and the distance between the central axes of the plurality of electronic components 20 is indicated by double-headed arrow C2. In addition, distance C1 between the central axis of the metal post 90 and the central axis of the electronic component 20 closest to the metal post 90 may substantially be equal to distance C2 between the central axes of the plurality of electronic components 20. It should be noted that, when distance C1 is substantially equal to distance C2, distance C2 need not exactly match distance C1, and the lower limit of distance C2 need only fall within the range of 95% to 105% of distance C1 when distance C1 is 100%. In addition, since the value of distance C1 and the value of distance C2 can be measured at a plurality of locations in a single cavity portion, the average value thereof is used. When the electronic components 20 and the metal posts 90 are disposed closest to each other in the single cavity portion 13, the relationship between distance C1 and distance C2 is the relationship described above. The space in the cavity portion 13 in which nothing is disposed may be small, and the electronic components 20 and the metal posts 90 may be disposed closely to effectively use the space in the cavity portion 13.

In FIG. 1, the dimension of the metal post 90 in the height direction is indicated by double-headed arrow H90, and the dimension of the electronic component 20 in the height direction is indicated by double-headed arrow H20. In addition, in the substrate 100 illustrated in FIG. 1, dimension H90 of the metal post 90 in the height direction parallel to the thickness direction of the core substrate 10 may be greater than dimension H20 of the electronic component 20 in the height direction. This is because, when the metal post 90 is provided in the cavity portion 13 during the manufacturing process of the substrate 100, which will be described later, a manufacturing method that grinds or polishes the upper end of the metal post 90 such that the first surface 11 of the core substrate 10 and the third surface 31 of the encapsulating material 30 are flush with the fifth surface 91 of the metal post 90 is used. Since the first electrode 21 of the electronic component 20 is not ground or polished, dimension H20 of the electronic component 20 in the height direction is smaller.

The difference between dimension H90 of the metal post 90 in the height direction and dimension H20 of the electronic component in the height direction may be, for example, 20 μm or more and 600 μm or less.

In the substrate 100 illustrated in FIG. 1, the heights of the fifth surfaces 91 of the metal posts 90 differ from the heights of the first surfaces 21 of the electronic components 20, and the heights of the sixth surfaces 92 of the metal posts 90 coincide with the heights of the second surfaces 22 of the electronic components 20. Accordingly, the fourth surface 32 of the encapsulating material 30 is flatter than the third surface 31 of the encapsulating material 30.

Fine wiring can be formed on the flatter fourth surface 32 of the encapsulating material 30. Accordingly, the finest line that is the line having the narrowest width of wires (lines) of the wiring layer 72 provided on the fourth surface 32 of the encapsulating material 30 may be finer than the finest line that is the finest of the widths (lines) of wires of the wiring layer 62 provided on the third surface 31 of the encapsulating material 30. As a result, finer vias and wiring can be formed on the fourth surface 32 of the encapsulating material 30 that is flatter than the third surface 31 of the encapsulating material 30.

In addition, the distance between wires arranged at equal intervals is referred to as spacing, and the minimum spacing between wires of the wiring layer 72 may be finer than the minimum spacing of wires of the wiring layer 62.

A combination of a line and spacing is referred to as a line and spacing, and wires having a finer line and spacing are finer wires. Since finer wires can be formed on the wiring layer 72, the minimum line and spacing of wires of the wiring layer 72 may be finest than the minimum line and spacing of wires of the wiring layer 62.

It should be noted that, when the substrate is manufactured using a different manufacturing method that, for example, cuts the metal post 90 to a predetermined length that is approximately the same as the longitudinal length of the electronic component 20 and places the cut metal post 90, dimension H90 of the metal post 90 in the height direction may be identical to dimension H20 of the electronic component 20 in the height direction, or dimension H90 of the metal post 90 in the height direction may be less than dimension H20 of the electronic component 20 in the height direction, but such cases are not excluded from the scope of the present disclosure.

The cross section of the substrate 100 illustrated in FIG. 1 is orthogonal to the second surface 12 of the core substrate 10, and in this cross section, the metal post 90 is disposed between the wall surface 13a of the cavity portion 13 and the electronic component 20, and accordingly, the linear expansion coefficient of the metal post 90 may be between the linear expansion coefficient of the core substrate 10 and the linear expansion coefficient of the electronic component 20. The linear expansion coefficient of a resin material used as the core substrate is approximately 40 ppm/K, the linear expansion coefficient of a multilayer ceramic capacitor assumed to be the electronic component is approximately 10 ppm/K, and heat stress that depends on the difference between the linear expansion coefficients is applied during a temperature change. The linear expansion coefficient of copper, assumed to be used for the metal post 90, is approximately 16, which is between the linear expansion coefficient of the core substrate 10 and the linear expansion coefficient of the electronic component 20. Accordingly, by the metal posts 90 being disposed between the wall surface 13a of the cavity portion 13 and the electronic component 20, that is, between the core substrate 10 and the electronic component 20, the effect of the difference between the linear expansion coefficient of the core substrate 10 and that of the electronic components 20 can be reduced, the heat stress applied between the core substrate 10 and the electronic components 20 can be reduced, and problems such as generation of cracks or the like due to the heat stress can be prevented from occurring.

The electronic component 20 and the metal post 90 have approximately the same shape and size in FIG. 2, but they may have the same shape and size or different shapes and sizes. When the metal post 90 is relatively large, the heat dissipation effect can be improved.

In a cross section parallel to the second surface of the substrate according to the present disclosure, the top-view shape of the electronic component may be a rectangle, and the top-view shape of the metal post is a round-chamfered polygon with four or more sides, a polygon with five or more sides, a circle, an ellipse, an oval, or a stadium shape.

In addition, the top view area of the metal post may be equal to or more than the top view area of the electronic component.

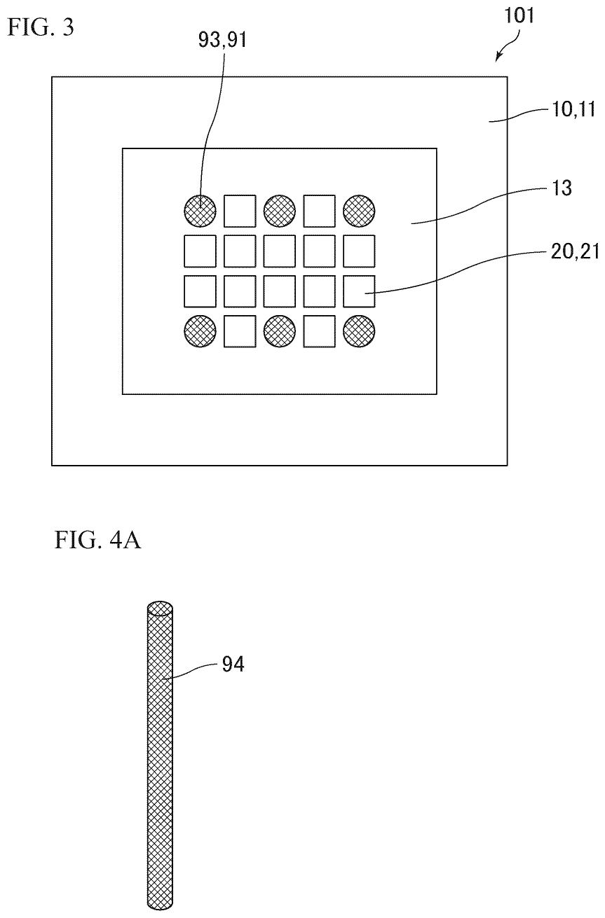

FIG. 3 is a plan view schematically illustrating an example of the substrate according to the embodiment of the present disclosure in which the top-view shape of the metal post differs. FIG. 3 illustrates a substrate 101 including metal posts 93 having a circular top-view shape. In addition, the top-view shape of the electronic component 20 of the substrate 101 is a rectangle with four angulated (non-chamfered) corners.

In the manufacturing method of the substrate (described in detail later), when the electronic components 20 are encapsulated with the encapsulating material 30, in vacuum, an unsolidified film including a thermosetting resin and fillers is laminated on the first surface 11 of the core substrate 10. Then, this film is heated and pressed to be softened, and the cavity portion 13 is filled with the thermosetting resin and the fillers. At this time, compared with the case in which the top-view shape of the electronic components 20 and the metal posts 90 is a rectangle as illustrated in FIG. 2, when the top-view shape of the metal posts 93 is a circle as illustrated in FIG. 3, the fluidity of the softened resin increases near the metal posts 93, bubbles are suppressed from being mixed, and fillers are suppressed from clogging, and accordingly, filling properties are improved. Since filling properties are improved, stress concentration can be prevented, and peeling, breakage, and damage of the resin can be prevented. Since this effect works when the top-view shape of the metal post is not angulated but round-chamfered, the top-view shape of the metal post may be a round-chamfered polygon with four or more sides, a polygon with five or more sides, a circle, an ellipse, an oval, or a stadium shape.

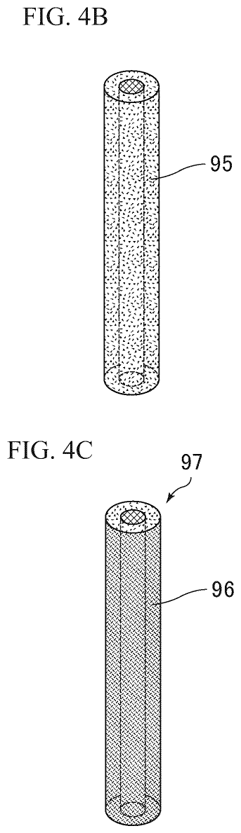

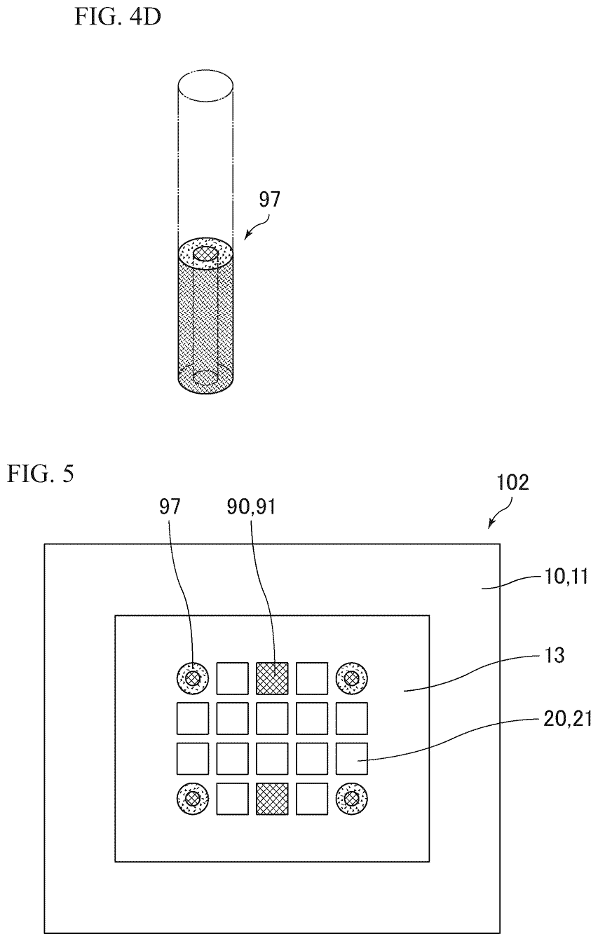

The metal post may be formed as a coaxial cable in which the outer periphery of a metal wire is covered with a resin coating layer and the outer periphery of the resin coating layer is covered with a metal coating layer. FIGS. 4A, 4B, 4C, and 4D are perspective views schematically illustrating an example of a manufacturing process of a coaxial cable. In addition, FIG. 5 is a plan view schematically illustrating an example of a substrate according to the embodiment of the present disclosure in which a portion of the metal post is the coaxial cable.

A coaxial cable 97 (see FIG. 4C) is obtained by the outer periphery of a metal wire 94 in FIG. 4A being covered with a resin coating layer 95 in FIG. 4B and the outer periphery of the resin coating layer 95 being covered with a metal coating layer 96 in FIG. 4C. When the coaxial cable is used as the metal post, the coaxial cable 97 is cut to have a length that is equal to or slightly longer than the thickness of the cavity portion 13 (see FIG. 4D).

The metal wire 94 and the metal coating layer 96 may be made of copper or a copper alloy. The resin coating layer 95 may be made of polyethylene, polytetrafluoroethylene (PTFE), tetrafluoroethylene perfluoroalkyl vinyl ether copolymer resin (PFA), or the like.

A substrate 102 illustrated in FIG. 5 includes the metal posts 90 made of metal and metal posts made from the coaxial cables 97. It is assumed that the coaxial cable 97 can also electrically connect the first surface 11 and the second surface 12 of the core substrate 10 to each other. In addition, since the coaxial cable 97 has good high-frequency characteristics, the coaxial cable 97 can be used as wiring for transmission of high-frequency signals. In addition, since it is difficult for the manufacturing process to cause the through-hole that is a conductor passing through the core substrate 10 to have a structure like the coaxial cable, wiring for vertical conduction having good high-frequency characteristics can be easily provided by the coaxial cable 97 being disposed in the cavity portion 13.

Although the substrate 102 illustrated in FIG. 5 includes both the metal posts 90 made of metal and the metal posts made from the coaxial cables 97, the substrate 102 may have only the coaxial cables 97 as the metal posts. In addition, the positional relationships between the metal posts made of a metal and the metal posts 90 made from the coaxial cables 97 and the ratio of the number thereof are also not particularly limited.

### (Module)

Next, a module according to the present disclosure in which a heating element has been mounted on the substrate according to the present disclosure will be described.

The module according to the present disclosure includes the substrate according to the present disclosure and a heating element mounted on the first surface of the core substrate, in which the heating element overlaps the metal post in top view in a direction orthogonal to the first surface, and the heating element and the metal post are directly connected to each other or connected to each other via a first material having a higher thermal conductivity than the encapsulating material.

In addition, in top view in a direction orthogonal to the first surface, the ratio of the area in which the heating element overlaps the metal post to the area of the heating element is 10% or more and 100% or less.

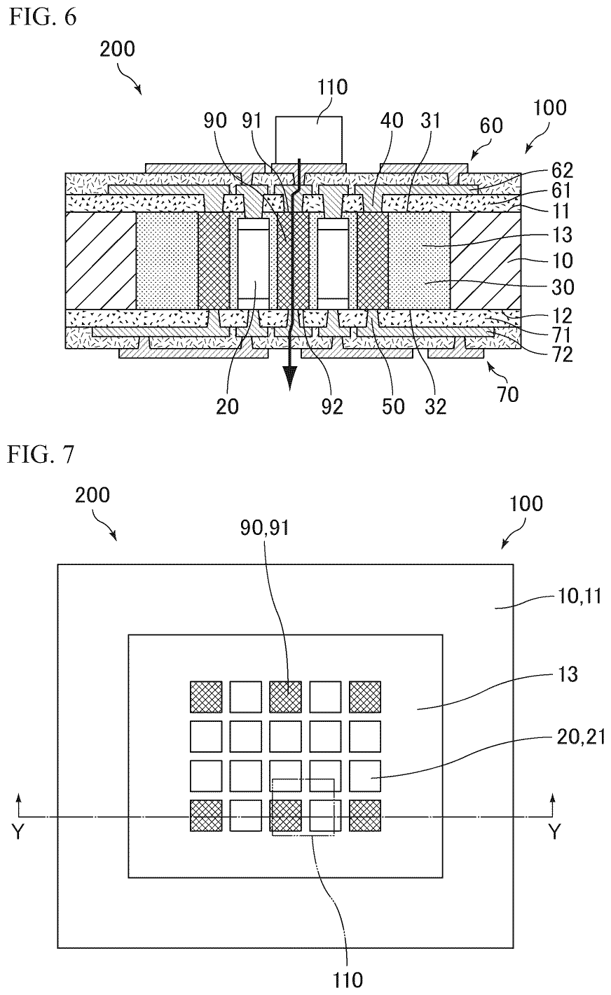

FIG. 6 is a sectional view schematically illustrating an example of the module according to an embodiment of the present disclosure. FIG. 7 is a plan view of the module in FIG. 6 and illustrates the positional relationship between the heating element and components of the substrate. It should be noted that FIG. 6 is a sectional view of the substrate taken along line Y-Y in FIG. 7, and the position of the heating element is denoted by a dot-dot-dash line in FIG. 7.

In a module 200 illustrated in FIGS. 6 and 7, a heating element 110 is mounted on the first surface 11 (more precisely, on the first buildup layer 60) of the core substrate 10 of the substrate 100 illustrated in FIGS. 1 and 2.

The heating element 110 may be an electronic component that is a semiconductor component, such as a CPU or memory, a light emitting device, such as a LED, or a passive component, such as an inductor or a capacitor. The heating element 110 is not particularly limited as long as it generates heat during use.

As illustrated in FIG. 7, the position at which the heating element 110 is mounted overlaps the position of the metal post 90 in top view in a direction orthogonal to the first surface 11. That is, the metal post 90 is located immediately below the heating element 110. In the positional relationship, the heat generated by the heating element 110 can be transferred (dissipated) to the second surface 12 of the core substrate 10 via the metal post 90. The path through which heat is dissipated from the heating element 110 is indicated by an arrow in FIG. 6. In addition, the heating element 110 may be electrically connected to the metal post 90 located immediately below it.

When the heating element and the metal post are electrically connected to each other, the heating element and the metal post may be directly connected to each other, or the heating element and the metal post may be connected via the first material having a higher thermal conductivity than the encapsulating material. The connection in FIG. 6 indicates the latter case, and the first material corresponds to the first via conductor 40 and the wiring layer 62 of the first buildup layer 60. The first via conductor 40 and the wiring layer 62 are electrically conductive and have a higher thermal conductivity than the encapsulating material 30. The first material may be a metal material, such as copper or a copper alloy. Since the thermal conductivity of the first material is higher than that of the encapsulating material 30, the heat from the heating element 110 is efficiently transferred to the metal post 90 via the first material.

Alternatively, when the heating element and the metal post are not electrically connected to each other, a relatively thin insulator or a high thermal conductive resin may be present between the heating element and the metal post to maintain thermal conductivity between the heating element and the metal post.

In addition, the thermal resistance of the path from the heating element to the fourth surface of the encapsulating material via the third surface of the encapsulating material and the metal post may be less than the thermal resistance of the path from the heating element to the fourth surface via the third surface of the encapsulating material without passing through the metal post.

In addition, a second material having a thermal conductivity higher than the encapsulating material may be provided on the second surface of the core substrate, and the metal post and the second material may be connected to each other. In FIG. 6, the second material corresponds to the second via conductor 50 and the wiring layer 72 of the second buildup layer 70. In FIG. 6, on the second surface 12 side of the core substrate 10, the metal post 90 and the second via conductor 50 are connected to each other and the wiring layer 72 is connected to the second via conductor 50. Since the second via conductor 50 and the wiring layer 72 are electrically conductive, when an electrical signal from the heating element 110 need be transmitted, the second via conductor 50 and the wiring layer 72 can transmit the signal to the second surface 12 of the core substrate.

In addition, when the thermal conductivity of the second via conductor 50 and the wiring layer 72 is higher than that of the encapsulating material 30, the heat from the heating element 110 can be transferred via the second material to a surface facing away from the surface on which the heating element 110 is mounted. The second material may be a metal material, such as copper or a copper alloy.

It should be noted that the module according to the present disclosure may have another heating element mounted on the second surface side of the core substrate in addition to the heating element mounted on the first surface side of the core substrate. In addition, one heating element or a plurality of heating elements may be mounted on the core substrate. When a plurality of heating elements are mounted, all heating elements may overlap the metal post in top view in a direction orthogonal to the first surface, but some of the heating elements need not overlap the metal post. When at least one heating element that overlaps the metal post is present in top view, the at least one heating element is included in the module according to the present disclosure. In addition, since there is no distinction between the first surface and the second surface of the core substrate of the substrate according to the present disclosure, when the heating element is mounted on one surface of the substrate, the surface on which the heating element is mounted is considered to be the first surface of the core substrate.

### (Method of Manufacturing Substrate)

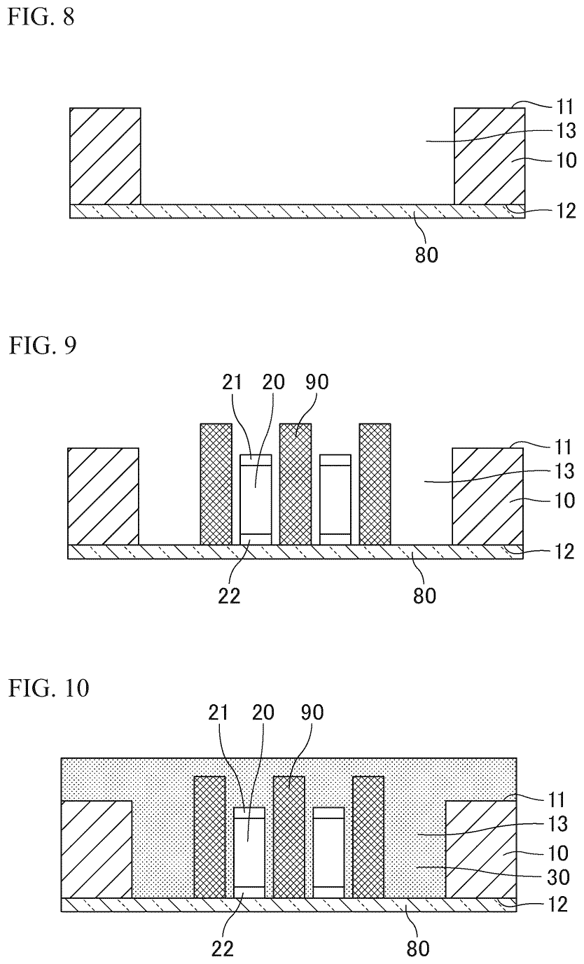

The substrate 100 can be manufactured by the following method. FIG. 8 is a diagram schematically illustrating an example of a process of attaching an adhesive film for fixing electronic components to the core substrate.

First, as illustrated in FIG. 8, the cavity portion 13 is formed in the core substrate 10, and the adhesive film 80 for fixing the electronic components and metal posts is attached to the second surface 12 of the core substrate 10. FIG. 9 is a sectional view schematically

illustrating an example of a process of disposing the electronic components and the metal posts on the adhesive film.

Next, as illustrated in FIG. 9, the electronic components 20 are disposed on the adhesive film 80. The electronic components 20 are disposed on the adhesive film 80 such that, for example, the first electrodes 21 face upward and the second electrodes 22 face downward. As a result, the second electrodes 22 are attached to the adhesive film 80. In addition, the metal posts 90 are also disposed on the adhesive film 80. The height of the metal posts 90 is set higher than the first electrodes 21 of the electronic components 20 and the first surface 11 of the core substrate 10.

FIG. 10 is a sectional view schematically illustrating an example of a process of filling a cavity portion of the core substrate with the encapsulating material.

Next, as illustrated in FIG. 10, the electronic components 20 and the metal posts 90 are encapsulated with the encapsulating material 30. Specifically, in vacuum, an unsolidified film including a thermo-setting resin and the fillers is laminated on the first surface 11 of the core substrate 10. Then, this film is heated and pressed to be softened, and the region around the electronic components 20 and the metal posts 90 in the cavity portion 13 is filled with the thermosetting resin and the fillers.

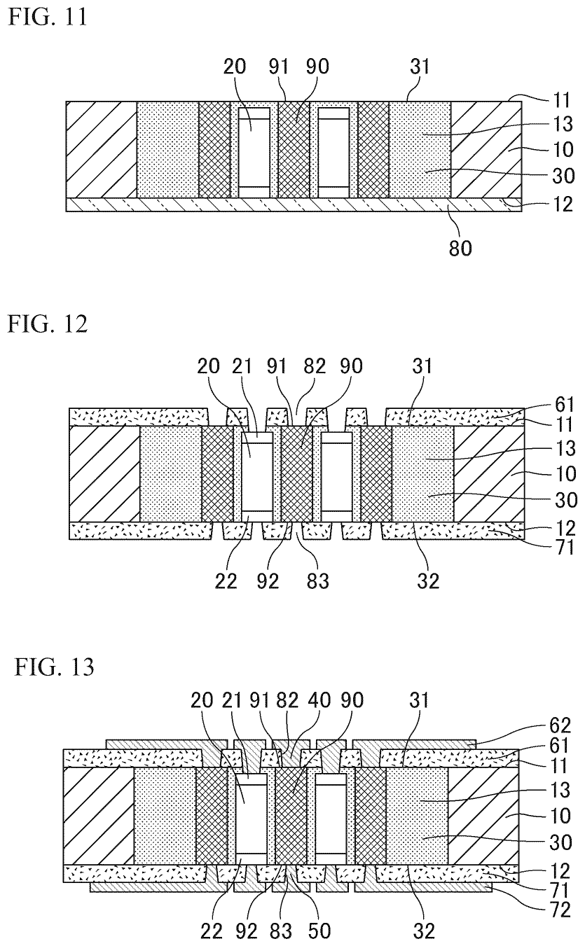

FIG. 11 is a sectional view schematically illustrating an example of a process of grinding or polishing the encapsulating material and the metal posts.

Next, as illustrated in FIG. 11, the encapsulating material 30 and the metal posts 90 are ground or polished on the first surface 11 side of the core substrate 10 such that the first surface 11 of the core substrate 10, the third surface 31 of the encapsulating material 30, and the fifth surfaces 91 of the metal posts 90 are flush with each other. After being ground or polished, the fifth surfaces 91 of the metal posts 90 are exposed through the third surface 31 of the encapsulating material 30. On the other hand, the first electrodes 21 of the electronic components 20 are covered with the encapsulating material 30 and are not exposed. In this process, the electronic components 20 are not ground or polished.

FIG. 12 is a sectional view schematically illustrating an example of a process of forming vias.

Next, as illustrated in FIG. 12, after the adhesive film 80 is removed, the insulating layer 61 is formed on the first surface 11 of the core substrate 10 and the third surface 31 of the encapsulating material 30, and the insulating layer 71 is formed on the second surface 12 (under the second surface 12 in FIG. 12) of the core substrate 10 and the fourth surface 32 of the encapsulating material 30. It should be noted that the adhesive film 80 can used continuously without being removed. Then, vias 82 are formed in the insulating layer 61 using a CO₂ laser or the like to expose the first electrodes 21 of the electronic components 20 and the fifth surfaces 91 of the metal posts 90, and vias 83 are formed in the insulating layer 71 using a CO2 laser or the like to expose the second electrodes 22 of the electronic components 20 and the sixth surfaces 92 of the metal posts 90. It should be noted that, when the vias 82 are formed, the encapsulating material 30 covering the first electrodes 21 of the electronic components 20 is also removed.

FIG. 13 is a sectional view schematically illustrating an example of a process of forming wiring layers.

Next, as illustrated in FIG. 13, the vias 82 and 83 are filled by using plating (for example, a semi-additive method) to form the first via conductor 40, the second via conductor 50, the wiring layer 62, and the wiring layer 72.

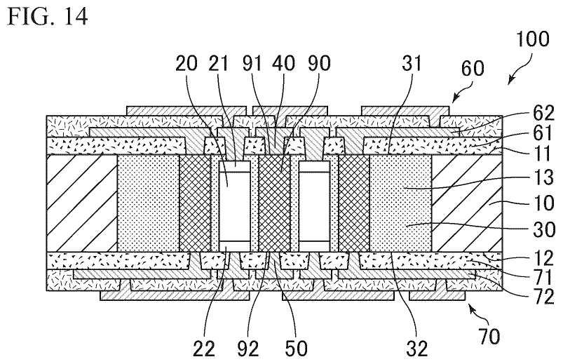

FIG. 14 is a sectional view schematically illustrating an example of a process of forming buildup layers.

After that, as illustrated in FIG. 14, layers are added as necessary to form the first buildup layer 60 and the second buildup layer 70.

As described above, the substrate 100 can be manufactured. In the substrate 100 manufactured by this process, the fifth surface 91 of the metal post 90 is flush with the third surface 31 of the encapsulating material 30, exposed through the third surface 31 of the encapsulating material 30, and connected to the first via conductor 40. In addition, the sixth surface 92 of the metal post 90 is flush with the fourth surface 32 of the encapsulating material 30, exposed through the fourth surface 32 of the encapsulating material 30, and connected to the second via conductor 50. In addition, the dimension of the metal posts 90 in the height direction is greater than the dimension of the electronic components 20 in the height direction.

The disclosure of this specification will be described below.

<1> A substrate comprising: a core substrate that has a first surface, a second surface facing away from the first surface, and a cavity portion therein; an electronic component and a metal post that are provided in the cavity portion; an encapsulating material that fills the cavity portion and has a third surface close to the first surface and a fourth surface close to the second surface, wherein the metal post is exposed through the third surface and the fourth surface of the encapsulating material.

<2> The substrate according to <1>, wherein the metal post has a shape in which a dimension in a height direction parallel to a thickness direction of the core substrate is greater than dimensions in other directions orthogonal to the height direction.

<3> The substrate according to <1> or <2>, wherein the electronic component generates heat during operation, and a distance between the metal post and the electronic component closest to the metal post is less than a distance between the metal post and a wall surface of the cavity portion.

<4> The substrate according to any one of <1> to <3>, wherein a plurality of electronic components are provided in the cavity portion, the electronic component being one of the plurality of the electronic components, and in a cross section parallel to the second surface, a distance between a central axis of the metal post and a central axis of the electronic component closest to the metal post is substantially identical to a distance between central axes of the plurality of electronic components.

<5> The substrate according to any one of <1> to <4>, wherein the dimension of the metal post in the height direction parallel to the thickness direction of the core substrate is greater than a dimension of the electronic component in the height direction.

<6> The substrate according to any one of <1> to <5>, wherein a linear expansion coefficient of the metal post is between a linear expansion coefficient of the core substrate and a linear expansion coefficient of the electronic component, and in a cross section orthogonal to the second surface, the metal post is disposed between the wall surface of the cavity portion and the electronic component.

<7> The substrate according to any one of <1> to <6>, wherein, in a cross section parallel to the second surface, a top-view shape of the electronic component is a rectangle, and a top-view shape of the metal post is a round-chamfered polygon with four or more sides, a polygon with five or more sides, a circle, an ellipse, an oval, or a stadium shape.

<8> The substrate according to any one of <1> to <7>, wherein the metal post is made of copper or a copper alloy.

<9> The substrate according to any one of <1> to <8>, wherein the metal post is shaped like a coaxial cable in which an outer periphery of a metal wire is covered with a resin coating layer and an outer periphery of the resin coating layer is covered with a metal coating layer.

<10> A module comprising: the substrate according to any one of <1> to <9>; and a heating element mounted on the first surface of the core substrate, wherein the heating element overlaps the metal post in top view in a direction orthogonal to the first surface, and the heating element and the metal post are directly connected to each other, or the heating element and the metal post are connected to each other via a first material having a higher thermal conductivity than the encapsulating material.

<11> The module according to <10>, wherein the first material is a metal material.

<12> The module according to <10> or <11>, wherein a second material having a higher thermal conductivity than the encapsulating material is provided on the second surface of the core substrate, and the metal post and the second material are connected to each other.

<13> The module according to <12>, wherein the second material is a metal material.

10 core substrate

11 first surface

12 second surface

13 cavity portion

13a wall surface of cavity portion

20 electronic component

21 first electrode

22 second electrode

30 encapsulating material

31 third surface

32 fourth surface

40 first via conductor

50 second via conductor

60 first buildup layer

61 insulating layer

62 wiring layer

70 second buildup layer

71 insulating layer

72 wiring layer

80 adhesive film

82, 83 via

90, 93 metal post

91 fifth surface

92 sixth surface

94 metal wire

95 resin coating layer

96 metal coating layer

97 coaxial cable

100, 101, 102 substrate

110 heating element

200 module

C1 distance between central axis of metal post and central axis of electronic component

C2 distance between central axes of a plurality of electronic components

D1 first direction

D2 second direction

H20 height of electronic component

H90 height of metal post

S1 distance between metal post and wall surface of cavity portion

S2 distance between metal post and electronic component

1. A substrate comprising:
a core substrate having a first surface, a second surface facing away from the first surface, and a cavity portion therein;
at least one electronic component and a metal post provided in the cavity portion; and
an encapsulating material filling the cavity portion and having a third surface close to the first surface and a fourth surface close to the second surface,
wherein the metal post is exposed through the third surface and the fourth surface of the encapsulating material.

2. The substrate according to claim 1,
wherein the metal post has a shape having a dimension in a height direction parallel to a thickness direction of the core substrate greater than each of dimensions in other directions orthogonal to the height direction.

3. The substrate according to claim 1,
wherein the electronic component is a heat-generating component during operation, and a distance between the metal post and one of the at least one electronic component closest to the metal post is less than a distance between the metal post and a wall surface of the cavity portion.

4. The substrate according to claim 1,
wherein the at least one electronic component comprises a plurality of electronic components provided in the cavity portion, and
in a cross section parallel to the second surface, a distance between a central axis of the metal post and a central axis of one of the plurality of electronic components closest to the metal post is substantially identical to a distance between central axes of the plurality of electronic components.

5. The substrate according to claim 1,
wherein the dimension of the metal post in the height direction parallel to the thickness direction of the core substrate is greater than a dimension of the electronic component in the height direction.

6. The substrate according to claim 1,
wherein a linear expansion coefficient of the metal post is between a linear expansion coefficient of the core substrate and a linear expansion coefficient of the electronic component, and
in a cross section orthogonal to the second surface, the metal post is disposed between a wall surface of the cavity portion and the electronic component.

7. The substrate according to claim 1,
wherein, in a cross section parallel to the second surface, a top-view shape of the electronic component is a rectangle, and a top-view shape of the metal post is a round-chamfered polygon with four or more sides, a polygon with five or more sides, a circle, an ellipse, an oval, or a race track shape.

8. The substrate according to claim 1,
wherein the metal post comprises copper or a copper alloy.

9. The substrate according to claim 1,
wherein the metal post comprises a coaxial cable, wherein an outer periphery of a metal wire in the coaxial cable is covered with a resin coating layer and an outer periphery of the resin coating layer is covered with a metal coating layer.

10. A module comprising:
the substrate according to claim 1; and
a heating element mounted on the first surface of the core substrate,
wherein the heating element overlaps the metal post in a top view in a direction orthogonal to the first surface, and
the heating element and the metal post are directly connected to each other or connected to each other via a first material having a higher thermal conductivity than the encapsulating material.

11. The module according to claim 10,
wherein the first material is a metal material.

12. The module according to claim 10,
wherein a second material having a higher thermal conductivity than the encapsulating material is provided on the second surface of the core substrate, and
the metal post and the second material are connected to each other.

13. The module according to claim 12,
wherein the second material is a metal material.

14. The substrate according to claim 2,
wherein the electronic component is a heat-generating component during operation, and a distance between the metal post and one of the at least one electronic component closest to the metal post is less than a distance between the metal post and a wall surface of the cavity portion.

15. The substrate according to claim 2,
wherein the at least one electronic component comprises a plurality of electronic components provided in the cavity portion, and
in a cross section parallel to the second surface, a distance between a central axis of the metal post and a central axis of one of the plurality of electronic components closest to the metal post is substantially identical to a distance between central axes of the plurality of electronic components.

16. The substrate according to claim 3,
wherein the at least one electronic component comprises a plurality of electronic components provided in the cavity portion, and
in a cross section parallel to the second surface, a distance between a central axis of the metal post and a central axis of one of the plurality of electronic components closest to the metal post is substantially identical to a distance between central axes of the plurality of electronic components.

17. The substrate according to claim 2,
wherein the dimension of the metal post in the height direction parallel to the thickness direction of the core substrate is greater than a dimension of the electronic component in the height direction.

18. The substrate according to claim 3,
wherein the dimension of the metal post in the height direction parallel to the thickness direction of the core substrate is greater than a dimension of the electronic component in the height direction.

19. The substrate according to claim 4,
wherein the dimension of the metal post in the height direction parallel to the thickness direction of the core substrate is greater than a dimension of the electronic component in the height direction.

20. The substrate according to claim 2,
wherein a linear expansion coefficient of the metal post is between a linear expansion coefficient of the core substrate and a linear expansion coefficient of the electronic component, and
in a cross section orthogonal to the second surface, the metal post is disposed between a wall surface of the cavity portion and the electronic component.
